(19) United States
(12) Patent Application Publication
(10) Pub. No.: US 2006/0289980 A1
(43) Pub. Date: Dec. 28, 2006

(54) Stacked memory card and method for manufacturing the same

(76) Inventors: Hong Tsu Chang, Hsinchu Hsien (TW); Dennis Pai, Hsinchu Hsien (TW); Frank Lung, Hsinchu Hsien (TW); Jay Lin, Hsinchu Hsien (TW); Wilson Huang, Hsinchu Hsien (TW); Men San Lung, Hsinchu Hsien (TW)

Correspondence Address: PRO-TECHTOR INTERNATIONAL, 20775 Norada Court, Saratoga, CA, 95070-3018, US

(21) Appl. No.: 11/165,114

(22) Filed: Jun. 22, 2005

(51) Int. Cl. H01L 23/02; H01L 21/00

(52) U.S. Cl. 257/679; 257/686; 438/109; 257/E23.085

(57) ABSTRACT

A structure of stacked memory card, the structure includes a substrate, a lower chip, wires, adhered element, upper chip, and compound resin. The substrate has an upper surface formed with a plurality of first electrodes, and a lower surface. The B-stage glue is coated on the upper surface of the substrate. The lower chip is arranged on the upper surface of the substrate, and is located on the B-stage glue. The plurality of wires are electrically connected the lower chip to the first electrode of the substrate. The adhesive element includes adhesive agent and filling elements is coated on the lower chip. The upper chip is adhered on the lower chip by adhesive element, and is spaced with the lower chip through the filling element, then is electrically connected to the first electrode of the substrate by wires. The compound resin is encapsulated on the upper chip, lower chip, and wires.

### BACKGROUND OF THE INVENTION

1. Field of the Invention

The invention relates to a stacked memory card and method for manufacturing the same, and particular to memory card with B-stage glue for forming a stacked memory card, the reliability of the stacked memory card may be promoted.

2. Description of the Related Art

A conventional stacked memory card includes upper chip and lower chip, the upper chip is adhered on the lower chip by way of non-conductive glue, and the lower chip is adhered on the substrate by the non-conductor glue, while the quality of the non-conductor glue is property, the lower chip is bumpy, so that the stacked memory card is bumpy.

### SUMMARY OF THE INVENTION

An objective of the invention is to provide a stacked memory card and a method for manufacturing the same capable of increasing the reliability of the stacked memory card.

To achieve the above-mentioned object, the invention includes a substrate, B-stage glue, lower chip, wires, an adhesive element, an upper chip, and a compound resin. The substrate has an upper surface formed with a plurality of first electrodes, and a lower surface. The B-stage glue is coated on the upper surface of the substrate. The lower chip is arranged on the upper surface of the substrate, and is located on the B-stage glue. The wires are electrically connected the lower chip to the first electrode of the substrate. The adhesive element includes an adhesive agent and filling elements coated on the lower chip. The upper chip is adhered on the lower chip by adhesive element, and spaced with the lower chip through the filling element, then is electrically connected to the first electrode of the substrate by wires. The compound resin encapsulated on the upper chip, lower chip, and wires.

### BRIEF DESCRIPTION OF THE DRAWINGS

FIG. 1 is a cross-sectional view schematic illustration showing a stacked memory card of the present invention.

FIG. 2 is a first illustration showing a method for manufacturing a stacked memory card of the present invention.

FIG. 3 is a second illustration showing a method for manufacturing a stacked memory card of the present invention.

FIG. 4 is a third illustration showing a method for manufacturing a stacked memory card of the present.

### DETAILED DESCRIPTION OF THE INVENTION

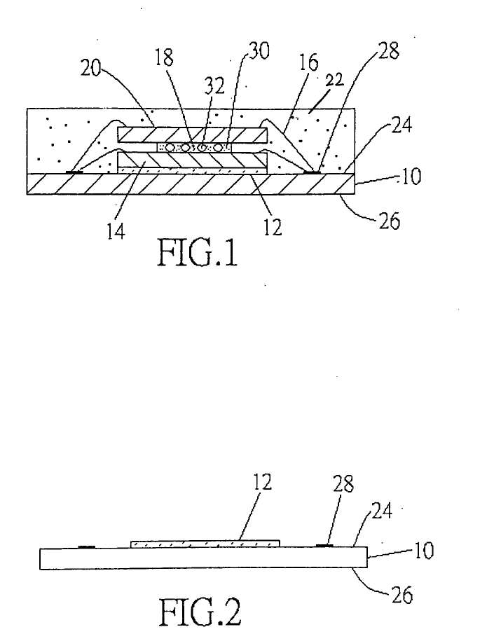

Please refer to FIG. 1 is a stacked memory card of the present invention includes a substrate 10, B-stage glue 12, lower chip 14, wires 16, an adhesive element 18, an upper chip 20, and a compound resin 22.

The substrate 10 has an upper surface 24 formed with a plurality of first electrodes 28, and a lower surface 26.

The B-stage glue 12 is coated on the upper surface 24 of the substrate 10 by printing matter.

The lower chip 14 is arranged on the upper surface 24 of the substrate 10, and is located on the B-stage glue 12.

The wires 16 are electrically connected the lower chip 14 to the first electrode 18 of the substrate 10.

The adhesive element 16 coated on the lower chip 14 includes an adhesive agent 30 and filling elements 32, in the embodiment, the filling elements 32 are ball sharp.

The upper chip 20 is adhered on the lower chip 14 by adhesive element 16, and is spaced with the lower chip 14 through the filling element 32, then is electrically connected to the first electrode 28 of the substrate 10 by wires 16.

The compound resin 22 is encapsulated on the upper chip 20, lower chip 14, and wires 16.

Please refer to FIG. 2 is a first illustration showing a method for manufacturing a stacked memory card of the present invention. Firstly, providing a substrate 10 having an upper surface 24 formed with a plurality of first electrodes 28, and a lower surface 26.

Providing B-stage glue 12 coated on the upper surface 24 of the substrate 10 by printing matter. Then, first curing the B-stage 12 coated on the substrate

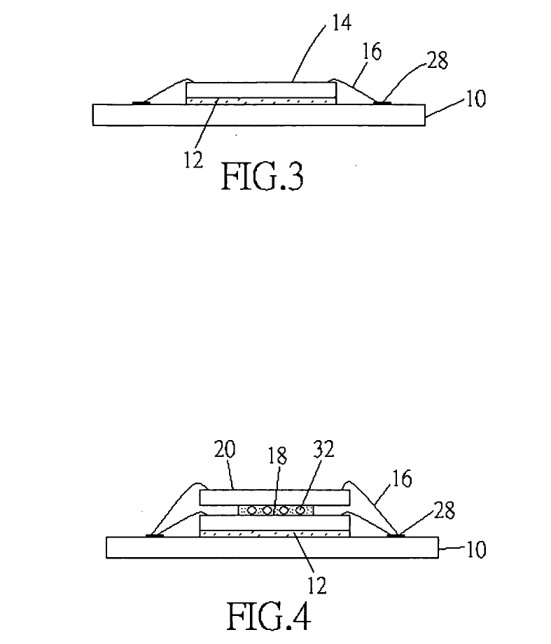

Please refer to FIG. 3 is a second illustration showing a method for manufacturing a stacked memory card of the present invention. Providing a lower chip 14 arranged on the upper surface 24 of the substrate 10, and located on the B-stage glue 12, curing the B-stage 12 coated on the substrate 10, thus, the lower chip 14 is mounted on the substrate 10.

Providing wires 16 electrically connected the lower chip 14 to the first electrode 18 of the substrate 10.

Please refer to FIG. 4 is a second illustration showing a method for manufacturing a stacked memory card of the present invention. Providing adhesive element 16 coated on the lower chip 14 has an adhesive agent 30 and filling elements 32, in the embodiment, the filling elements 32 are ball sharp.

Providing an upper chip 20 adhered on the lower chip 14 by adhesive element 16, and spaced with the lower chip 14 through the filling element 32, then is electrically connected to the first electrode 28 of the substrate 10 by wires 16.

Finally, providing a compound resin 22 encapsulated on the upper chip 20, lower chip 14, and wires 16.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

1. A structure of stacked memory card, comprising;
a substrate having an upper surface formed with a plurality of first electrodes, and a lower surface;
a B-stage glue coated on the upper surface of the substrate;
a lower chip arranged on the upper surface of the substrate, and located on the B-stage glue;
a plurality of wires electrically connected the lower chip to the first electrode of the substrate;
a adhesive element including adhesive agent and filling elements coated on the lower chip;
an upper chip adhered on the lower chip by adhesive element, and spaced with the lower chip through the filling element, then electrically connected to the first electrode of the substrate by wires; and
a compound resin encapsulated on the upper chip, lower chip, and wires.

2. (canceled)

3. (canceled)

4. A method for manufacturing a substrate of memory card, the method comprising the step of;
Providing a substrate having an upper surface formed with a plurality of first electrodes, and a lower surface;
Providing a B-stage glue coated on the upper surface of the substrate, and first curing the B-stage glue;
Providing a lower chip arranged on the upper surface of the substrate, and located on the B-stage glue, and second curing the B-stage glue, so as to the lower chip fixed on the substrate;
Providing a plurality of wires electrically connected the lower chip to the first electrode of the substrate;
Providing a adhesive element including adhesive agent and filling elements coated on the lower chip;
Providing an upper chip adhered on the lower chip by adhesive element, and spaced with the lower chip through the filling element, then electrically connected to the first electrode of the substrate by wires; and
Providing a compound resin encapsulated on the upper chip, lower chip, and wires.

5. The structure of stacked memory card according to claim 1, wherein the B-stage glue is coated on the lower chip by printing way.

6. The structure of stacked memory card according to claim 1, wherein the filling elements are balls.
